(19) United States
(12) Patent Application Publication
(10) Pub. No.: US 2007/0171156 A1
(43) Pub. Date: Jul. 26, 2007

(54) DISPLAY DEVICE

(75) Inventors: Haruo KAWAKAMI, Hino-shi, Tokyo (JP); Hisato KATO, Hino-shi, Tokyo (JP); Keisuke YAMASHIRO, Hino-shi, Tokyo (JP)

Correspondence Address: ROSSI, KIMMS & McDOWELL LLP., P.O. BOX 826, ASHBURN, VA, 20146-0826, US

(73) Assignee: FUJI ELECTRIC HOLDINGS CO., LTD., Kawasaki-ku (JP)

(21) Appl. No.: 11/561,173

(22) Filed: Nov. 17, 2006

Related U.S. Application Data
(63) Continuation of application No. PCT/JP05/08236, filed on Apr. 28, 2005.

(30) Foreign Application Priority Data
May 17, 2004 (JP) JP 2004-145815
Dec. 27, 2004 (JP) JP 2004-375556

(51) Int. Cl. G09G 3/30

(52) U.S. Cl. 345/76

(57) ABSTRACT

The organic EL display device includes first and second sets of stripe electrodes; third and fourth sets of stripe electrodes crossing the stripe electrodes of the first and second sets; and pixels, each including a light emitting section, one of the electrodes of which is connected electrically to the stripe electrode of the first set, a transistor element connected electrically to the stripe electrode of the fourth set and to the other electrode of the light emitting section, the transistor element controlling the current flowing through the light emitting section, a first rectifying element connected to the gate electrode of the transistor element and the stripe electrode of the second set, a second rectifying element connected to the gate electrode of the transistor element and the stripe electrode of the third set, and a capacitor connected to the gate electrode of the transistor element and the stripe electrode of the fourth set.

This is a continuation of International Application PCT/JP2005/008236, having an international filing date of Apr. 28, 2005, which International application claims priority to JP 2004-145815, filed May 17, 2004, and JP 2004-375556, filed Dec. 27, 2004, the contents of which are incorporated by reference.

### TECHNICAL FIELD

The present invention relates to a self-light-emitting display device for organic EL (electroluminescence) display panels. Specifically, the invention relates to a display device that drives pixels, which emit light, arranged on a matrix formed of a plurality of lines and a plurality of columns.

### BACKGROUND ART

Recently, liquid crystal displays have been very widely used as flat panel displays for information equipment. The liquid crystal display conducts ON/OFF control of the back lights using the optical shutter function of the liquid crystal and obtains colors using color filters. In contrast, since each pixel in the organic EL display (or in the organic LED display) emits light (conducts self-light-emission), the organic EL display has a wide angle of visibility. Moreover, since the organic EL display does not require any back light, it is possible to make the organic EL display thin and to form the organic EL display on a flexible substrate. The organic EL display exhibits many advantages as described above. Therefore, the organic EL display has been expected as a display of the next generation.

The systems for driving the organic EL display panel may be roughly classified into a first driving system and a second driving system. The first driving system is called a “passive matrix system”. (The passive matrix system is called also a “duty driving system” or a “simple matrix system.”) The organic EL display panel employing the passive-matrix system combines a plurality of stripe electrodes to form lines and columns, constituting a matrix, and makes the pixel at the cross point of a relevant line electrode and a relevant column electrode emit light with the driving signals fed to the relevant line electrode and column electrode. Usually, the signals for light emission control are made to scan the lines one by one in a time sequence and applied simultaneously to the columns on a same line. Usually, each pixel is not provided with any active element. The pixels on each line are controlled to emit light for the duty period assigned to the relevant line within the scanning period of the line.

The second driving system is called an “active matrix system.” The active matrix system provides each pixel with a switching element and makes it possible for the pixels to emit light over the scanning period of the relevant line. To explain the merits of the active matrix system, it is assumed that the entire panel area having a matrix of 100 lines×150 columns is made to emit light at the display luminance of 100 Cd/m². Since the pixels in the active matrix system always emit light fundamentally, it is good to make the pixels emit lights at 100 Cd/m² as far as the area factor of the pixels and various losses are not considered. However, if one wants to obtain the same display luminance by the passive matrix system, it will be necessary to set the light emitting luminance in the light emitting period to be 10000 Cd/m², 100 times as high as the light emitting luminance by the active matrix system, since the duty ratio is 1/100, at which each pixel in the passive matrix system is driven, and since each pixel in the passive matrix system is made to emit light only in the duty period (selected period). For increasing the light emitting luminance, it is effective to increase the current fed to the organic EL element. However, it has been known that the light emitting efficiency of the organic EL decreases as the current fed to the organic EL element increases. Due to the lowering of efficiency, the electric power consumption in the passive matrix system will be larger than the electric power consumption in the active matrix system, if both driving systems are compared with each other at the same display luminance. As the current fed to the organic EL element increases, the materials thereof are more liable to be deteriorated by heat generation, and the life of the display device is shortened. If the maximum current is limited from the view points of efficiency and life, it will be necessary to elongate the light emitting period to obtain the same display luminance. However, since the duty ratio that determines the light emitting period for the passive matrix system is the inverse of the number of lines in the panel, the elongation of the light emitting period causes limitation on the display capacity (number of driving lines). In view of the foregoing, to obtain a large-area and high-definition panel, it has been necessary to employ the active matrix driving system. As the fundamental circuits for the ordinary active matrix driving, a TFD system as shown in FIG. 1, which employs a thin film rectifying element for the switching element thereof, and a system as shown in FIG. 2, which employs thin film transistors for the switching elements thereof, are known.

A thin film transistor (TFT) using polysilicon has been used most widely as the switching element for a pixel in the active matrix driving system suited for a large-area and high-definition display panel. However, since the temperature of the process for forming a TFT that uses polysilicon is high, e.g., at least 250° C. or higher, it is difficult to use a flexible plastic substrate.

The use of an organic switching element has been proposed to obviate the various problems of the conventional organic EL display panels. The Publication of Unexamined Japanese Patent Application 2001-250680 (Patent Document 1) discloses a series connection of an organic thin film rectifying element and an organic thin film light emitting section. The Publication of WO01/15233 (Patent Document 2) discloses a pixel drive control with an organic thin film transistor. As disclosed in the Patent Document 2, since the driving element is made of an organic material, it is possible to employ a low-temperature manufacturing process and, therefore, to use a flexible plastic substrate. Since it is possible to select an inexpensive material and an inexpensive process, the driving element is manufactured with low manufacturing costs.

### DISCLOSURE OF INVENTION

Problems to be Solved by the Invention

However, the following problems are posed on driving the light emitting section, which includes an organic EL, using an organic thin film rectifying element or an organic thin film transistor.

In driving the light emitting element using the organic thin film rectifying element as shown in FIG. 1, the light emission from the light emitting element is sustained by discharging the electric charges, accumulated in a capacitor during the duty period of the light emitting element, outside the duty period (in the non-duty period). Since the electrical resistance of the organic EL light emitting section is very high at a low voltage generally, the electric charges in the capacitor are decreased very slowly by discharge after the capacitor voltage has lowered below a certain value. Since the electric charges, which have remained in the capacitor until the next duty period, affect the amount of light emitted in the next frame period, it is necessary to remove the electric charges remaining in the capacitor so that the previous history may be prevented from adversely effecting performance. Although it is possible to remove the remaining electric charges through a discharge line prepared separately for initializing data and such a means, electric power is consumed ineffectively, since the electric power discharged during the electric charge removal does not contribute to light emission. Since the current for charging up the capacitor is fed through the organic thin film rectifying element, large electric power consumption is caused in the organic thin film rectifying element. Although the electric power consumption in the organic EL is suppressed by not limiting the light emitting period to the duty period, electric power consumption is caused in the peripheral elements.

In driving a light emitting element using organic thin film transistors as shown in FIG. 2, the switching signal for a TFT1 for driving is fed via a TFT2 for switching to the gate of the driving TFT1. Since the switching TFT2 is ON during the duty period and the signal fed through a data signal line Y2 is accumulated in a capacitor C, the driving TFT1 is held to be ON even outside the duty period. In the configuration described above, it is enough for the capacitance of the capacitor C to be as high as to hold the driving TFT1 to be ON. Therefore, the electric power losses as caused in the above described case, in which an organic thin film rectifying element is employed, due to the discharge of the remaining electric charges are not caused in the configuration described above, although electric power losses are caused between the source and drain of the driving TFT1. It is required for the switching TFT in this system to work at a high frequency such as around 50 kHz. If one wants to make pixels on 480 lines work at a frame frequency of 120 Hz, it will be necessary to switch ON and OFF the switching TFT for a duty period of 1/120/480 sec, that is 17.4 μsec (at the frequency of 57 kHz). However, it is impossible for the presently available organic thin film transistors to conduct switching operations at such a high speed as described above. The organic thin film transistors used mainly these days are field effect type ones, which obtain electrical conductivity by applying an electric field to an organic thin film from a gate electrode via an insulator film to accumulate electric charges in the vicinity of the insulator film. This operation principle is equivalent to charging the capacitor including the insulator film. If one assumes that the electric charges are fed from the source and drain electrodes, the response frequency will be determined by the impedance on the path between the capacitor and the source electrode, the impedance on the path between the capacitor and the drain electrode, and the capacitor capacitance. Therefore, it is considered that there exists a certain limit on the response frequency.

In view of the foregoing, it is an object of the invention to form a display device such as an organic EL display panel on an inexpensive and flexible substrate.

It is another object of the invention to stabilize the gradation reproducibility when an organic thin film rectifying element is used for a switching element.

Means for Solving the Problems

According to the invention, there is provided a display device including:
a substrate;
a first set of stripe electrodes formed in parallel to each other on the substrate;
a second set of stripe electrodes formed on the substrate corresponding to the respective stripe electrodes of the first set, the stripe electrodes of the second set being formed in parallel to each other and in parallel to the stripe electrodes of the first set;
a third set of stripe electrodes formed in parallel to each other on the substrate, the stripe electrodes of the third set crossing the stripe electrodes of the first and second sets;
a fourth set of stripe electrodes formed on the substrate corresponding to the respective stripe electrodes of the third set, the stripe electrodes of the fourth set being formed in parallel to each other and in parallel to the stripe electrodes of the third set;
pixels at the respective points on the substrate, thereat any of the stripe electrodes of the first set and any of the stripe electrodes of the fourth set cross each other on two levels;
each of the pixels including:
a light emitting section, one of the electrodes thereof is connected electrically to the stripe electrode of the first set corresponding to the each of the pixels;
a transistor element connected electrically to the stripe electrode of the fourth set corresponding to the each of the pixels and the other one of the electrodes of the light emitting section to control the current flowing through the light emitting section from the stripe electrode of the first set to the stripe electrode of the fourth set or vice versa in the each of the pixels;
a first rectifying element connected electrically to the gate electrode of the transistor element and the stripe electrode of the second set corresponding to the each of the pixels;
a second rectifying element connected electrically to the gate electrode of the transistor element and the stripe electrode of the third set corresponding to the each of the pixels;
a capacitor connected electrically to the gate electrode of the transistor element and the stripe electrode of the fourth set corresponding to the each of the pixels; and
the first rectifying element and the second rectifying element being connected such that the forward direction of the first rectifying element and the forward direction of the second rectifying element coincide with each other between the stripe electrodes of the second and third sets in the each of the pixels.

According to the invention, there is provided a display device including:
a substrate;
a first set of stripe electrodes formed in parallel to each other on the substrate;
a second set of stripe electrodes formed on the substrate corresponding to the respective stripe electrodes of the first set, the stripe electrodes of the second set being formed in parallel to each other and in parallel to the stripe electrodes of the first set;
a third set of stripe electrodes formed in parallel to each other on the substrate, the stripe electrodes of the third set crossing the stripe electrodes of the first and second sets;
a fourth set of stripe electrodes formed on the substrate corresponding to the respective stripe electrodes of the third set, the fourth set being formed in parallel to each other and in parallel to the stripe electrodes of the third set;
a fifth set of stripe electrodes formed on the substrate corresponding to the respective stripe electrodes of the third set, the stripe electrodes of the fifth set being formed in parallel to each other and in parallel to the stripe electrodes of the third and fourth sets;
pixels at the respective points on the substrate, thereat any of the stripe electrodes of the first set and any of the stripe electrodes of the fourth set cross each other on two levels;
each of the pixels including:
a light emitting section, one of the electrodes thereof is connected electrically to the stripe electrode of the first set corresponding to the each of the pixels;
a transistor element connected electrically to the stripe electrode of the fourth set corresponding to the each of the pixels and the other one of the electrodes of the light emitting section to control the current flowing through the light emitting section from the stripe electrode of the first set to the stripe electrode of the fourth set or vice versa in the each of the pixels;
a first rectifying element connected electrically to the gate electrode of the transistor element and the stripe electrode of the second set corresponding to the each of the pixels;
a second rectifying element connected electrically to the gate electrode of the transistor element and the stripe electrode of the third set corresponding to the each of the pixels;
a capacitor connected electrically to the gate electrode of the transistor element and the stripe electrode of the fifth set corresponding to the each of the pixels; and
the first rectifying element and the second rectifying element being connected such that the forward direction of the first rectifying element and the forward direction of the second rectifying element coincide with each other between the stripe electrodes of the second and third sets in the each of the pixels.

According to the invention, there is provided the method of addressing the pixels through column electrodes formed of the second set of stripe electrodes and line electrodes formed of the third set of stripe electrodes to drive any of the display devices described above, the method including:
the first step of bringing, in the duty period of a selected line, at least the first rectifying element or the second rectifying element into the electrically conductive state thereof through the line electrode and/or the column electrode to apply a signal that brings the transistor element into the electrically conductive state thereof to the gate electrode of the transistor element via the first rectifying element and to accumulate electric charges in the capacitor;
the second step of applying, in the duty period of the selected line, a signal, which brings the first rectifying element into the electrically nonconductive state thereof, through the line electrode and/or the column electrode;
the third step of holding, in the non-duty period of the selected line, the voltage applied to the gate electrode of the transistor element with the electric charges accumulated in the capacitor to hold the current flowing through the light emitting section;
the fourth step of bringing, in the next duty period subsequent to the preceding duty period, the second rectifying element into the electrically conductive state thereof through the line electrode and/or the column electrode to release the electric charges remaining in the capacitor through the second rectifying element; and
the fifth step of applying, in the next duty period, a signal that brings the second rectifying element into the electrically nonconductive state thereof through the line electrode and/or the column electrode.

In accumulating electric charges in the capacitor section via a rectifying element, the signal that facilitates making a current enough to accumulate the electric charges flow is applied corresponding to the characteristics of the rectifying element. The electric charges are made to work for realizing the desired light emitting luminance and gradation display is conducted corresponding to the electric charge quantity.

It is preferable for the electric charges, made to flow between the source and drain of the transistor for making the light emitting section emit light, to be large enough to realize the desired light emitting luminance.

For bringing the rectifying element into the electrically nonconductive state, the signals, which facilitate suppressing the leakage current leaking through the rectifying element to be low enough so that the rectifying element may be deemed to be electrically nonconductive practically, are employed. Since the signals as described above are applied through the line and column electrodes to the rectifying and transistor elements and to the light emitting and capacitor sections connected thereto, it is preferable for the signals to be suited for making the rectifying and transistor elements conduct ON-OFF operations thereof appropriately.

The above described fourth and fifth steps and the first and second steps may be conducted in a predetermined first window period and in a predetermined second window period. The first and second window periods are the periods of time set in the duty period of every selected line in the order of the above description. Since the fourth and fifth steps are conducted for erasing the previous history by releasing the remaining electric charges and since the first and second steps correspond to writing the next signals, it is desirable to conduct the steps in the order of the above description.

When the rectifying element exhibits low resistance at a high voltage and high resistance at a low voltage, matrix driving is facilitated, since it is possible to charge up the capacitor via the rectifying element by applying a high voltage to the rectifying element and since the electric charges accumulated in the capacitor do not leak through the rectifying element as the voltage lowers.

According to the invention, there is provided a display device that facilitates improving the gradation characteristics thereof, the display device including:
a substrate;
a set of stripe-shaped data electrodes formed in parallel to each other on the substrate;
a set of stripe-shaped scanning electrodes formed in parallel to each other on the substrate, the scanning electrodes crossing the data electrodes;
pixels at the respective points on the substrate, thereat any of the data electrodes and any of the scanning electrodes cross each other on two levels;
each of the pixels including: a light emitting section, a transistor element controlling the current flowing through the light emitting section, a rectifying element, and the gate electrode of the transistor element being connected electrically to the relevant data electrode via the rectifying element; and
constant current circuits connected electrically to the respective data electrodes.

According to the invention, the rectifying element preferably has a laminate structure formed of an aluminum thin film, a fullerene thin film, and a copper thin film or a laminate structure formed of an aluminum electrode, a pentacene compound, and a metal electrode. Many other organic electronic materials may be used for the rectifying element.

Although pentacene, hexythiophene polymers, fluorenethiophene polymers, copper phthalocyanine, and fullerene are preferable for the thin film transistor, many other organic electronic materials may be used for the thin film transistor. Although the transistors may be classified into a lateral transistor, in which a current flows in parallel to the electrodes thereof, and a vertical transistor, in which a current flows in perpendicular to the electrodes thereof, both the lateral organic thin film transistor and the vertical organic thin film transistor may be used with no problem.

Various metal oxides such as the oxides of silicon, aluminum, tantalum, titanium, strontium, and barium, anodic oxide films of these metals, and mixtures of these oxides may be used for the capacitor. Since the effective dielectric permeability of the dielectric layer is increased by dispersing electrically conductive small particles into an organic material, a capacitor section having a small area but exhibiting sufficient capacitance is obtained and used with no problem. Since it is possible to form the latter capacitor through a low-temperature process, the latter capacitor is preferable when a plastic substrate is used.

The constant current circuit used according to the invention is a circuit that holds the current value thereof at a certain value as long as the voltage applied to both ends of the driving terminal thereof varies within a certain range. Although several circuit configurations such as a circuit configuration that uses a pentode or a circuit configuration that uses a bipolar transistor are known, the circuit configuration that uses a field effect transistor is the most suitable from the viewpoints of applicable voltage range, current value and response. The current adjusted at a certain value is controlled easily with the gate voltage of the field effect transistor. Although the constant voltage source used according to the invention may be obtained with various means, the combination of a Zener diode and an operational amplifier is used generally.

Effects of the Invention

According to the invention, the transistor element, rectifying element, light emitting element, and capacitor are all formed of an organic electronic material thin film of around 100 nm in thickness and metal electrode thin films of around 100 nm in thickness. Therefore, the transistor element, rectifying element, light emitting element, and capacitor are employed easily for the cost reduction of the display device, for providing the display device with a large area, and for applying a flexible substrate to the display device. The display device according to the invention facilitates realizing multiple-level gradation display with low costs. The display device according to the invention also facilitates stabilizing the gradation reproducibility when a rectifying element is used for the element for switching.

### BRIEF DESCRIPTION OF DRAWINGS

FIG. 1 is an equivalent circuit diagram of a conventional display device that employs a rectifying element for the switching element thereof.

FIG. 2 is an equivalent circuit diagram of another conventional display device that employs thin film transistors for the switching elements thereof.

FIG. 3 is an equivalent circuit diagram of a display device according to the invention.

FIG. 4 is a schematic describing a matrix structure for the display device according to the invention.

FIGS. 5(a) through 5(d) show top plan views describing the structure of the display element according to the invention.

FIGS. 6(a) through 6(d) also show top plan views describing the structure of the display element according to the invention.

FIG. 7(a) through 7(h) describes the method of applying a voltage to each pixel in the duty and non-duty periods according to the invention.

FIGS. 8(a) and 8(b) are drawings describing the characteristics of the thin film transistors according to Example 1 of the invention. FIG. 8(a) describes the relations between the drain voltage and the drain current under the condition of constant gate voltages. FIG. 8(b) describes the relations between the gate voltage and the drain current under the condition of a constant drain voltage (−10 V).

FIG. 9 is an equivalent circuit diagram of another display element according to the invention.

FIG. 10 is a graph describing the current vs. voltage characteristics of an organic thin film rectifying element.

FIG. 11 is an equivalent circuit diagram of a display element according to the invention.

FIG. 12 is a diagram describing the matrix structure of the display device according to the invention.

FIG. 13(a) through 13(d) are timing charts describing the examples of voltage applications to each display element in the duty and non-duty periods according to the invention.

FIG. 14 shows a set of curves describing the operation characteristics of the constant current circuit according to the invention.

FIG. 15 is a graph describing the relation between the gradation levels and the accumulated voltages according to an example of the invention.

FIG. 16 is a graph describing the relation between the gradation levels and the accumulated voltages according to another example of the invention.

FIG. 17 is a graph describing the relation between the gradation levels and the accumulated voltages according to still another example of the invention.

### EXPLANATION OF NUMBERS

| | |
|---|---|
| 10: | Pixel |
| 80, 82, 84: | Wiring |
| 101: | Substrate |
| 103: | X3 line electrode (Scanning electrode) |
| 104: | X4 line electrode |
| 105: | Transparent electrode |
| 106: | Capacitor |
| 108: | X5 electrode |
| 110: | Light emitting section |
| 116: | Y2 column electrode (Data electrode) |
| 117: | Y1 column electrode |
| 121: | Rectifying element (TFD) |
| 122: | Rectifying element (TFD) |
| 123: | Rectifying element |
| 130: | Transistor element |
| 131: | Source electrode |
| 132: | Gate electrode |
| 134: | Gate insulator film |
| 135: | Organic electronic material film |
| 136: | Capacitor dielectric layer |
| 137: | Organic electronic material for rectifying element |
| 138: | Insulator film |
| 140: | Channel section |
| 150: | Constant current circuit |
| 151: | Constant voltage source |
| 702: | Duty period |
| 704: | Non-duty period |

### BEST MODES FOR CARRYING OUT THE INVENTION

### Embodiment 1

SUMMARY

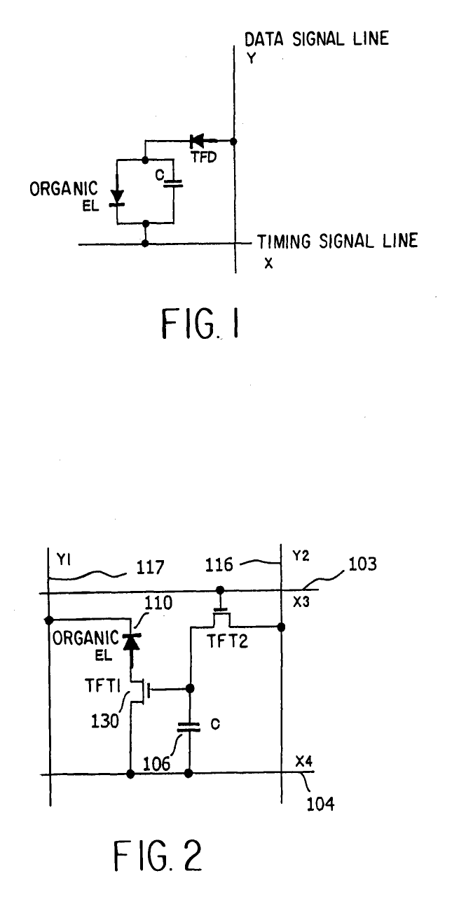

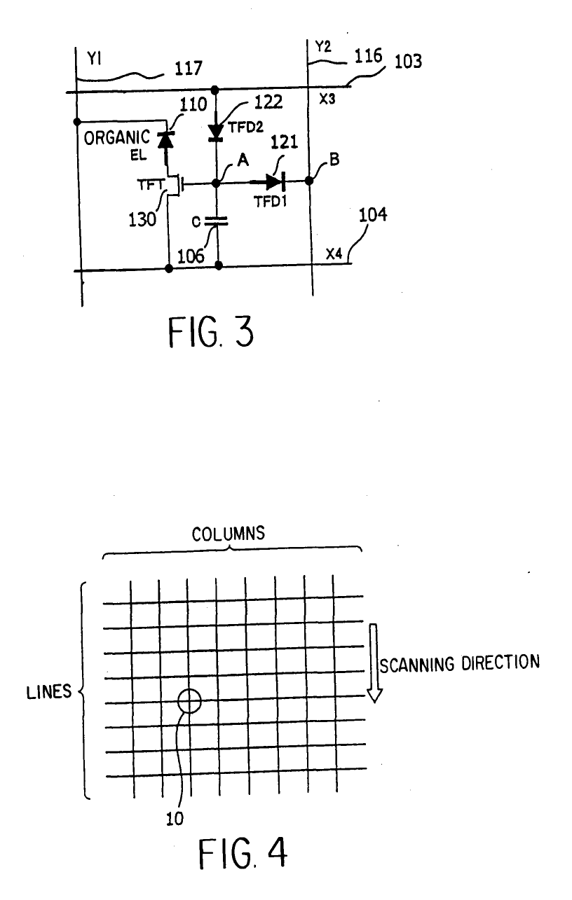

FIG. 3 shows a circuit configuration according to Embodiment 1 of the invention. The circuit configuration shown in FIG. 3 feeds a signal current via rectifying elements 121 and 122 in the same way as in the circuit configuration shown in FIG. 1. However, since the current flowing through the rectifying elements is used solely for holding the gate voltage of transistor element 130, the electric power losses caused in the rectifying elements in FIG. 3 are small. Since it is enough for capacitor 106 to compensate the leakage current caused in the gate electrode, the capacitance thereof may be small with no problem and the electric charges are prevented from being discharged in the next frame. The electric charges to be discharged are released to third stripe electrode (X3 electrode) 103 via the second rectifying element. The circuit configuration shown in FIG. 3 is different from the circuit configuration shown in FIG. 2 in that the gate voltage of the driving TFT is controlled via the rectifying elements in the circuit configuration shown in FIG. 3. Since the electrical capacitance caused by the insulator film in the TFT is not caused in the rectifying element fundamentally and since the response time is determined by the traveling speed of electric charges in the relevant rectifying element, it is possible for the rectifying element to work faster than the TFT.

Now the control sequence for controlling the light emission from the pixels in the display device according to the invention will be described below. The display device according to the invention conducts dot matrix display by the duty driving system that addresses pixels 10 through Y2 column electrodes 116, which are a second set of stripe electrodes, and X3 line electrodes 103, which are a third set of stripe electrodes (cf FIG. 4). In the first step of the light emission control according to the invention, at least first rectifying element 121 or second rectifying element 122 is made electrically conductive through X3 line electrodes 103 and/or Y2 column electrodes 116 in the duty period of a selected line and a signal for making transistor element 130 electrically conductive is applied to the gate electrode of transistor element 130 via first rectifying element 121 and accumulated in capacitor 106. In the second step, a signal for making first rectifying element 121 electrically nonconductive is applied through X3 line electrodes 103 and/or Y2 column electrodes 116. In the third step, the voltage applied to the gate electrode of transistor element 130 is sustained with the electric charges accumulated in capacitor 106 in the non-duty period of the selected line to sustain the current flowing through light emitting section 110. In the fourth step, second rectifying element 122 is made electrically conductive through X3 line electrodes 103 and/or Y2 column electrodes 116 in the next duty period and the electric charges remaining in capacitor 106 are discharged via second rectifying element 122. In the fifth step, a signal for making second rectifying element 122 electrically nonconductive is applied through X3 line electrodes 103 and/or Y2 column electrodes 116.

According to the Embodiment 1 of the invention, electric charges are accumulated, corresponding to the amount of light to be emitted, via first rectifying element 121 in the capacitor connected to the gate portion of transistor element 130 contained in the pixel on the line driven in the duty period thereof in the pixel matrix and the current flowing through light emitting section 110 via transistor element 130 is sustained with the potential sustained by capacitor 106 in the non-duty period to continue light emission.

According to the embodiment 1, transistor element 130, controlling a current with an excellent stability and connected in series to the light emitting section, is used as a driving element. Further, rectifying elements 121 and 122 capable of working at a high speed are used for the elements for controlling the transistor current. When glass and such a heat-resisting material are used for the substrate, oxide ceramics may be used for capacitor 106. For example, excellent capacitor 106 is obtained by depositing a layer of barium-strontium titanate, which is a layer of a typical ferroelectric and several hundreds nm in thickness, by the RF magnetron sputtering method and by thermally treating the deposited barium-strontium titanate layer at around 650° C. When a plastic substrate is used, the dielectric layer of capacitor 106 is made of an organic dielectric material, into which electrically conductive small particles are dispersed.

In the duty period, electric charges are accumulated via these rectifying elements in capacitor 106 connected to the gate of transistor element 130 on each line. In the non-duty period, each pixel is isolated electrically from the second stripe electrode and such a signal line by rectifying elements 121 and 122 and transistor element 130 is held to be ON by the electric charges accumulated in the capacitor. Light emission is sustained by making a current flow through organic EL light emitting section 110 from a Y1 column electrode, which is a first stripe electrode, and an X4 line electrode, which is a fourth stripe electrode, via transistor element 130 made to be ON throughout the duty and non-duty periods. The emitted light intensity is controlled by controlling the gate opening of transistor element 130 with the voltage applied to the gate portion thereof.

[Details]

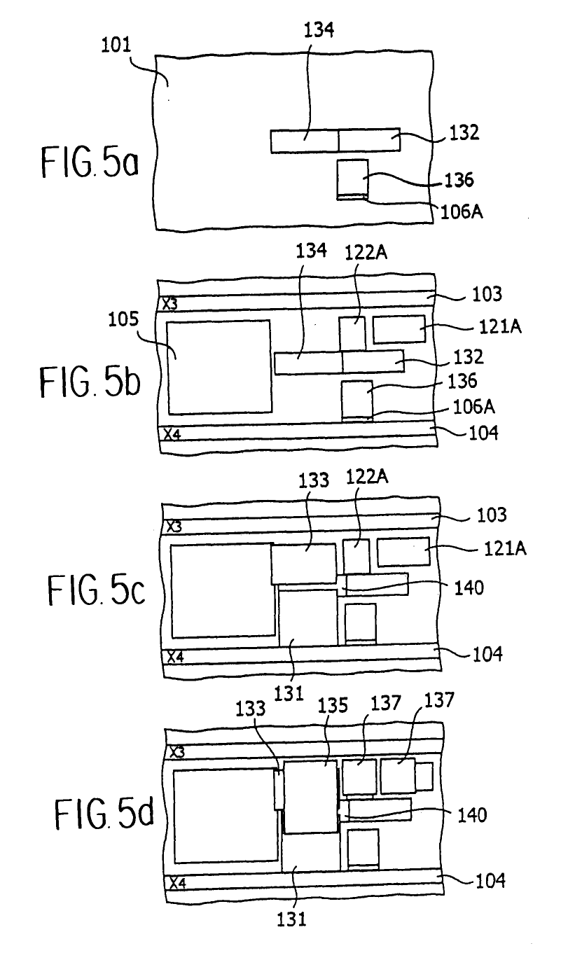

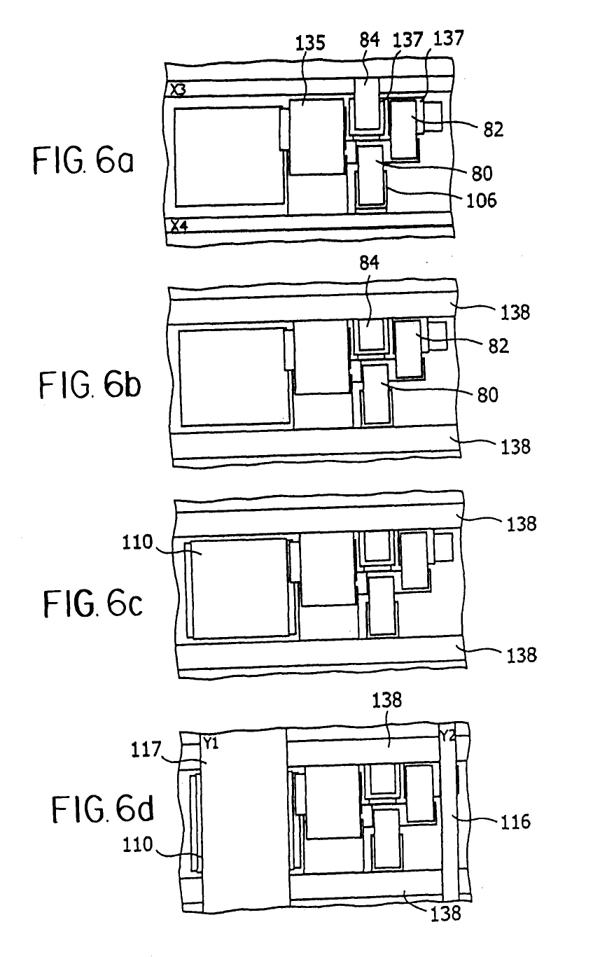

FIGS. 5 and 6 show top plan views describing the structure of the display section of the display device according to the embodiment 1 of the invention exemplary by a pixel expanded. In FIGS. 5 and 6, top plan views are described in the order of the manufacturing steps. Since an expanded pixel is described in these drawings, the patterned entire display device is not described in FIGS. 5 and 6. First for manufacturing a display device according to the Embodiment 1, gate electrode 132 and capacitor electrode 106A for capacitor 106 are patterned and formed on a major surface of plastic substrate 101. Then, a masking is conducted with a photoresist and an insulating film is formed on a part of gate electrode 132 and capacitor electrode 106A. The top plan view at this stage is shown in FIG. 5(a). The insulator film on gate electrode 132 works for gate insulator film 134. The insulator film on capacitor electrode 106A works for capacitor dielectric layer 136. Gate electrode 132 and capacitor electrode 106A may be made of various electrically conductive materials. The insulator film may be made of various insulators. When anodic oxidation of gate electrode 132 and capacitor electrode 106A is employed for the method of forming the insulator films, it is preferable to connect both electrodes electrically with each other in advance. In this case, it is possible to dispose aluminum wiring for the anodic oxidation treatment and to remove the wiring after the insulator films are formed such that gate electrode 132 and capacitor electrode 106A are insulated electrically from each other.

Then, X3 line electrode 103, X4 line electrode 104, transparent electrode 105, electrode 121A for a thin film rectifying element TFD1, and electrode 122A for a thin film rectifying element TFD2 are formed. The X3 line electrode 103 and X4 line electrode 104 are the so-called “timing signal lines” or “X electrodes” (e.g., FIG. 3). The X3 line electrode 103 and X4 line electrode 104 are patterned to be a plurality of stripe electrodes extending in parallel to each other. The X4 line electrode 104 is connected electrically to capacitor electrode 106A. Electrode 122A for the thin film rectifying element TFD2 is connected electrically to gate electrode 132 (FIG. 5(b)).

Next, source electrode 131 and drain electrode 133 of the thin film transistor are patterned and formed. Although both electrodes are formed of a gold vapor deposition film, a chromium film or an organic film may be used with no problem as an underlayer for improving the adhesion of the electrodes to the gate insulator film. Source electrode 131 is connected electrically to X4 line electrode 104 and drain electrode 133 to transparent electrode 105 such that channel section 140 is formed on gate insulator film 134 at a certain spacing (FIG. 5(c)).

Then, organic electronic material films 135 and 137 are formed such that film 135 covers channel section 140 of the thin film transistor and such that films 137 cover electrode 121A for the thin film rectifying element TFD1 and electrode 122A for the TFD2. In some cases, an underlayer treatment such as covering channel section 140 of the thin film transistor with an organic monomolecular layer is added to improve the crystallinity of organic electronic material films 135 and 137 (FIG. 5(d)).

Further, wiring 80 connecting gate electrode 132 and capacitor 106, wiring 82 connecting gate electrode 132 and the TFD1, and wiring 84 connecting the TFD2 and X3 line electrode 103 are formed of gold vapor deposition films (FIG. 6(a)).

Then, insulation treatment is conducted with insulator film 138 that covers X3 line electrode 103 and X4 line electrode 104 (FIG. 6(b)).

Next, light emitting section 110 including an organic EL element is formed on transparent electrode 105. Light emitting section 110 includes electrodes in the upper surface thereof (FIG. 6(c)).

Then, Y2 column electrode 116 and Y1 column electrode 117 are made of a metal. The Y2 column electrodes 116 are patterned to be a plurality of stripe-shaped electrodes extending in parallel to each other such that Y2 column electrodes 116 are connected to the portions of respective electrodes 121A for TFD1's not covered with any organic electronic material and crossing X3 line electrodes 103 and X4 line electrodes 104. The Y1 column electrodes 117 are patterned to be a plurality of stripe-shaped electrodes extending in parallel to each other such that Y1 column electrodes 117 are connected to the upper electrodes of light emitting sections 110 and crossing X3 line electrodes 103 and X4 line electrodes 104. Gate insulator film 134 is disposed so that Y2 column electrode 116 and Y1 column electrode 117 may short-circuit neither with X3 line electrode 103 nor with X4 line electrode 104. Due to the disposition of the insulator film, Y1 column electrode 117 is connected in the pixel only to the upper electrode of light emitting section 110 and Y2 column electrode 116 is connected in the pixel only to the lower surface of TFD1 121. The Y2 column electrode 116 and Y1 column electrode 117 are sometimes referred to as “data signal lines” or “Y electrodes” (e.g., FIG. 3). The electrodes, the organic EL element, the thin film transistor, the thin film rectifying element, and the capacitor section are formed of respective thin films. The currents of the organic EL element and the thin film rectifying element flow in perpendicular to the film planes thereof (FIG. 6(d)).

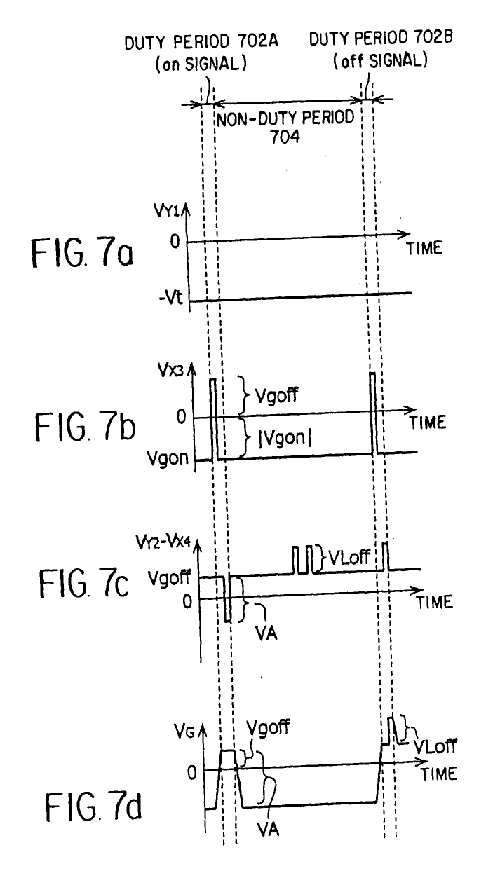

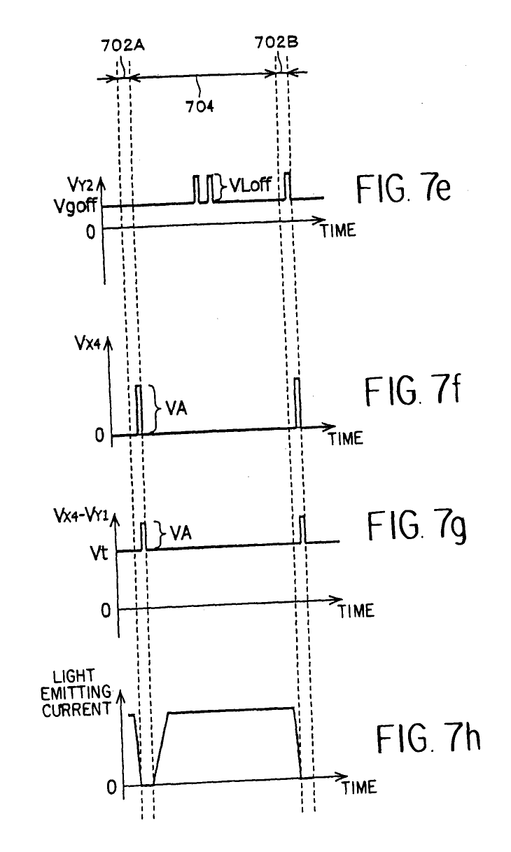

FIG. 7 schematically describes voltage waveforms in a pixel: the voltage waveform (FIG. 7(a)) applied to Y1 column electrode 117, the voltage waveform (FIG. 7(b)) applied to X3 line electrode 103, the voltage waveform (FIG. 7(e)) applied to Y2 column electrode 116, the voltage waveform (FIG. 7(f)) applied to X4 line electrode 104, the waveform (FIG. 7(d)) of the gate voltage VG (A portion) of the thin film transistor calculated from the above described voltages, the voltage waveform (FIG. 7(c)) applied to the rectifying element TFD1 and to the capacitor, the voltage waveform (FIG. 7(g)) applied between the source and drain of the transistor and to the light emitting section, and the waveform (FIG. 7(h)) of a light emitting current. The reference for 0 V is set at a potential, at which the voltage of the Y1 column electrode 117 is −Vt.

Generally, the rectifying element exhibits nonlinearity such that the resistance thereof becomes low in a high voltage region. A bias voltage −Vt is applied to Y1 column electrode 117 (FIG. 7(a)). Here, Vt is the sum of the drain voltage (VSD) of the transistor and the voltage drop (VEL) across the organic EL. For example, a bias voltage Vgoff is applied to Y2 column electrode 116 and a light emission control signal voltage VLoff (=Vgoff−Vgon) for each pixel is superimposed thereon (FIG. 7(e)). In this case, the signal VLoff is applied for a writing signal in writing the OFF-state but not applied in writing the ON-state. Alternatively, it is possible to apply a bias voltage (2Vgoff−Vgon) to Y2 column electrode 116, for example, and to superimpose a signal (−Vgoff+Vgon) in writing the OFF-state with no problem. The signal Vgon is applied to X3 line electrode 103 and the voltage of X3 line electrode 103 is changed to Vgoff in the first halves of the duty periods 702A and 702B (FIG. 7(b)). As described later, the gate voltage VG in the non-duty period 704 is changed to Vgon in the duty period 702A, in which the ON-state is written, and to Vgoff in the duty period 702B, in which the OFF-state is written. By setting the voltage of X3 line electrode 103 first at Vgoff in the first halves of the duty periods 702A and 702B, the gate voltage VG is initialized to be Vgoff (FIG. 7(d)).

A positive bias voltage VA (=Vgoff−Vgon) is applied to X4 line electrode 104 in the second halves of the duty periods 702A and 702B (FIG. 7(f) to reduce the resistance of TFD1 121 so that TFD1 121 may be in the electrically conductive state. At this instance, the X3 line electrode 103 is set at Vgon and the TFD2 122 is biased in reverse such that the TFD2 122 is in the insulated state. The gate voltage VG is Vgoff in the initialized state. The gate voltage VG may increase to (Vgoff+VA)=(2Vgoff−Vgon) due to the potential increase of the X4 line electrode 104.

This possibility will be described more in detail with reference to FIG. 7(d). As the signal VLoff is superimposed onto the Y2 column electrode 116 so that the potential thereof may be (2Vgoff−Vgon) as illustrated in the duty period 702B, the TFD1 121 is kept in the reverse bias state thereof and the gate potential is set at (2Vgoff−Vgon). As the potential of the X4 line electrode 104 is returned to the ground potential at the end of the duty period, the gate potential returns to Vgoff (FIG. 7(d)). The writing of the OFF-state is conducted as described above. As the potential of the Y2 column electrode 116 is set at Vgoff in the above described process as illustrates as the duty period 702A, the TFD1 121 is biased with a forward bias voltage ((2Vgoff−Vgon)>Vgoff) and the gate potential is set at Vgoff (FIG. 7(d)). As the potential of the X4 line electrode 104 is returned to the ground potential at the end of the duty period, the gate potential is set at Vgon. The writing of the ON-state is conducted as described above.

During the non-duty period, the potential of the X4 line electrode 104 is set at 0 V. Although the potential of the Y2 column electrode 116 is set at Vgoff or (2Vgoff−Vgon) during the non-duty period due to the writing into the other lines, no interference is caused between the lines, since the TFD1 121 is held in the OFF-state in any of the states of the Y2 column electrode 116. Although the potential difference between the Y1 column electrode 116 and the X4 line electrode 104 increases by VA in the second half of the duty period, no current flows through the organic EL, since the TFT 130 is in the OFF-state thereof. Corresponding to this, the current, which flows between the source and drain of the transistor and in the light emitting section, changes with elapse of time as shown in FIG. 7(h).

### EXAMPLE 1

Gate electrodes 132 made of tantalum and capacitor electrodes 106A made of tantalum were formed on glass substrate 101 through the usual photo-process and by sputtering. Each of the electrodes was 100 μm in width and 150 nm in thickness. Ten thousand pairs of the electrodes, formed of 100 electrode lines and 100 electrode columns arranged at a line pitch of 500 μm and a column pitch of 800 μm, were formed. Then, although not illustrated, aluminum wirings for electrically connecting the electrodes were formed. Then, masking was conducted with a photoresist and anodic oxide films were formed on a part of gate electrode 132 and capacitor electrode 106A, resulting in gate insulator film 134 and capacitor dielectric layer 136. Anodic oxidation was conducted in a solution containing 1 wt. % of ammonium borate for 50 minutes under the voltage of 70 V. The anodic oxide films were 80 nm in thickness. After the anodic oxidation, the aluminum wirings connecting the electrodes electrically were removed by a treatment using a basic solution.

Then, X3 line electrode 103, X4 line electrode 104, transparent electrode 105 of ITO (indium tin oxide), electrode 121A for the thin film rectifying element TFD1, and electrode 122A for the TFD2 were formed by patterning through photo-processes. Although not illustrated, photoresist partition walls were formed between the electrodes to prevent the electrodes from short-circuiting.

The stripes of X3 line electrodes 103 and the stripes of X4 line electrodes 104 were formed by the vacuum deposition of aluminum alternately such that 100 pairs of X3 line electrode 103 and X4 line electrode 104 were formed. The electrodes were arranges at a pitch of 500 μm. The electrodes were 30 μm in width and 100 nm in thickness. Both electrodes were spaced apart for 410 μm from each other. Gate electrode 132 and capacitor electrode 106A were formed between X3 line electrode 103 and Y4 line electrode 104. Then, transparent electrode 105 made of ITO (indium tin oxide) was formed by sputtering. Aluminum electrode 121A for the thin film rectifying element TFD1 and aluminum electrode 122A for the thin film rectifying element TFD2 were formed by vacuum deposition. The effective dimensions of the ITO (indium tin oxide) electrode were 300 μm×400 μm. The effective dimensions of any of capacitor electrode 106A, electrode 121A for the TFD1, and electrode 122A for the TFD2 were 100 μm×100 μm.

Then, source electrode 131 and drain electrode 132 of the thin film transistor were formed of a laminate of chromium and gold deposited by vapor deposition. The chromium film was 5 nm in thickness, the gold film 80 nm in thickness, the channel length 5 μm, and the channel width 100 μm. Then, organic electronic material films 135 and 137, both 80 nm in thickness, were formed by vacuum deposition of pentacene (supplied from Sigma-Aldrich Corporation). The substrate temperature at the time of the film formation was 60° C.

Further, the wiring connecting gate electrode 132 and capacitor 106, the wiring connecting gate electrode 132 and the TFD1, and the wiring connecting the TFD2 and X3 line electrode 103 were formed by the vapor deposition of copper.

Then, an insulation treatment was conducted by forming insulator film 138, made of perfluorotetracosane (n-C24F50) and 200 nm in thickness, by vacuum deposition such that X3 line electrode 103 and X4 line electrode 104 were covered with insulator film 138 (FIG. 6(b)).

Then, an organic EL layer, having a structure of copper phthalocyanine (CuPC) (supplied from Sigma-Aldrich Corporation)/naphthylphenyldiamine (NPB) (supplied from Sigma-Aldrich Corporation)/aluminum quinoline (Alq3) (supplied from Sigma-Aldrich Corporation)/a calcium electrode, was formed as a light emitting element on transparent electrode 105. The constituent layers of the structure were deposited by vacuum deposition in the order of the above description. The CuPC layer was 100 nm in thickness, the NPB layer 50 nm in thickness, the Alq3 layer 50 nm in thickness, and the calcium electrode layer 100 nm in thickness.

Then, a plurality of Y2 column electrodes 116, patterned to be a plurality of stripe-shaped electrodes extending in parallel to each other, was formed of aluminum vapor deposition films such that Y2 column electrodes 116 were connected to the portions of electrodes 121A for the TFD1's not covered with any organic electronic material and such that Y2 column electrodes 116 crossed X3 line electrodes 103 and X4 line electrodes 104. In the same manner as described above, a plurality of Y1 column electrodes 117, connected to the upper electrodes of light emitting sections 110, was formed of aluminum vapor deposition films, patterned to be a plurality of stripes extending in parallel to each other such that Y1 column electrodes 117 crossed X3 line electrodes 103 and X4 line electrodes 104.

The vapor deposition apparatus used for the above described film formations was evacuated by a diffusion pump. The vapor depositions were conducted under the degrees of vacuum of 4×10⁻⁴ Pa (3×10−6 torr). The depositions of aluminum, copper, and pentacene were conducted by resistance heating. The film deposition rate was 10 nm/sec for aluminum, 10 nm/sec for copper, and 0.4 nm/sec for pentacene.

### EXAMPLE 2

The sample according to Example 2 was obtained in the same manner as the sample according to Example 1 except that organic electronic material 137 for the rectifying elements was a laminate of a co-vapor deposition film of pentacene and F4TCNQ (containing 2 concentration % of F4TCNQ) (40 nm) and a pentacene film (40 nm) according to Example 2.

### EXAMPLE 3

The sample according to Example 3 was obtained in the same manner as the sample according to Example 1 except that a dielectric layer of 80 nm in thickness was formed for capacitor dielectric layer 136 by vacuum co-vapor deposition using aminoimidazole dicyanate (compound 1) as an insulating organic material and aluminum as electrically conductive small particles. The vapor deposition was conducted by resistance heating. The film deposition rate was 20 nm/sec for aminoimidazole dicyanate and 10 nm/sec for aluminum.
(Compound 1)

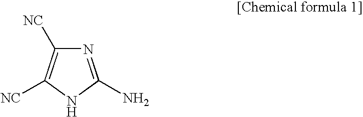

### EXAMPLE 4

The sample according to Example 4 was obtained in the same manner as the sample according to Example 1 except for the steps described below. According to Example 4, a platinum vapor deposition film having planar dimensions of 100 μm×30 μm and a thickness of 50 nm was formed for capacitor electrode 106A. Further, a barium-strontium titanate film of 100 nm in thickness was formed on the platinum film by the RF magnetron sputtering method and the ordinary photolithographic method and, then, the laminate was treated thermally in an oxygen atmosphere for 1 hour to form capacitor dielectric layer 136.

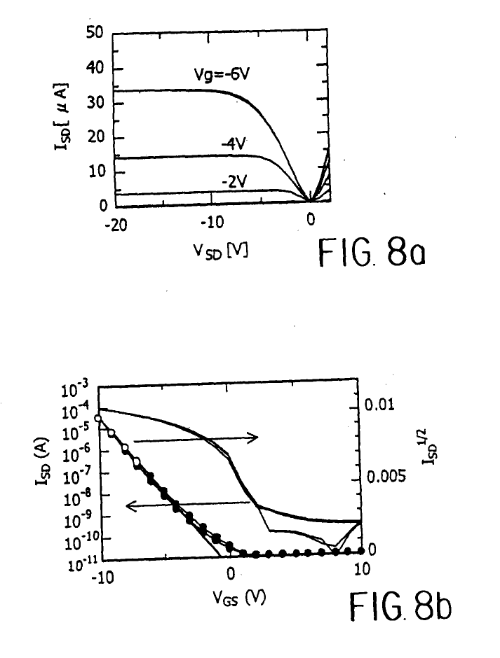

FIG. 8 describes the typical characteristics of the thin film transistors in the samples according to the above described examples of the invention. Under the condition, under which the gate voltage was −4 V and the drain voltage was −10 V, the drain current of 14 μA was obtained. A gate voltage VB of +3 V was obtained, at which the drain current became sufficiently small.

A manufactured display device was driven at the frame frequency of 60 Hz (frame period of about 17 ms). Although the duty period is 17 ms/100=170 Ps, the duty period is divided into two according to the invention. Therefore, it is necessary for the response time of the voltage control of the gate portion to be at least 85 μs or shorter. The response time is determined by the rectifying element resistance and the capacitor capacitance. The time constants, obtained from the rectifying element resistance and the capacitor capacitance, of the examples according to the invention are listed in Table 1. It was possible to conduct a sufficient response in this duty period.

TABLE 1

| | Rectifying element | Capacitor | |
|---|---|---|---|
| | resistance | capacitance | Time constants |
| Example 1 | 330 kΩ | 27 pF | 8.9 μs |
| Example 2 | 210 kΩ | 27 pF | 5.7 μs |
| Example 3 | 330 kΩ | 55 pF | 18 μs |
| Example 4 | 330 kΩ | 270 pF | 30 μs |

When Vgoff was set at 7 V, VX at 4 V, Vt at 16 V, VA at 4 V, and VLon at 0 V and 7 V according to the examples of the invention, the gate voltage was adjusted to be +3 V and −4 V such that the transistor was well controlled to be in the OFF- and ON-states thereof. The obtained current ratio of both states was about 10⁵.

Especially, in the ON-state, in which the gate voltage was −4 V, a drain current of 14 μA was obtained, causing a voltage drop of 6 V across the organic EL. Since Vt was 16 V, the transistor drain voltage was −10 V, i.e., in the saturation region as described in FIG. 8. Since the transistor is in the saturation region, a condition preferable for securing stable operations of emission of light of the display device is obtained even when resistance change is caused in the organic EL.

As described above, measures for manufacturing, on an inexpensive and flexible substrate, a display device such as an organic EL display panel using a switching element made of an organic electronic material have been obtained.

### Embodiment 2

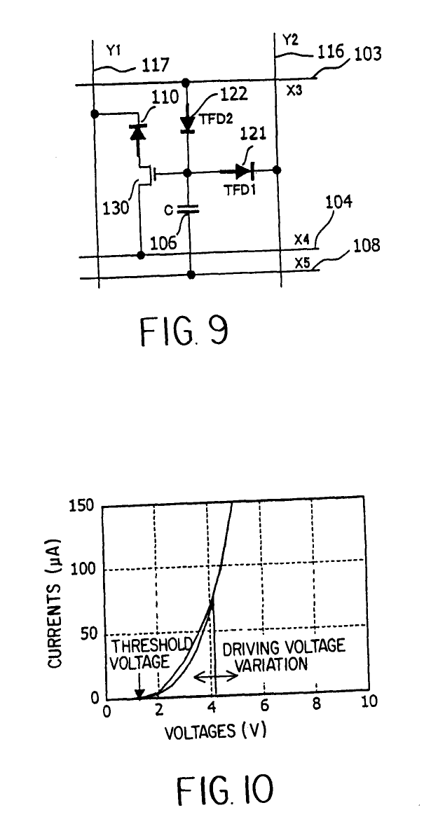

FIG. 9 shows the structure of a display device according to Embodiment 2 of the invention. Now the structure shown in FIG. 9 is compared with the structure shown in FIG. 3. The structure according to Embodiment 2 includes an improvement that disposes a stripe-shaped X5 electrode 108, connected to the capacitor terminal on the side opposite to the side of the other capacitor terminal connected to the gate electrode of the TFT, separately from stripe electrode 104, to which the TFT electrode is connected. Since the above described structure employed makes it unnecessary to modulate the voltage as applied to stripe electrode 104 even in writing the data, it is possible for stripe electrode 104 to stably feed a high current for driving the light emitting element. For X5 electrodes 108, high-speed modulation for a signal applied to the electrode is necessary in writing the data. However, the load of the modulator circuit is reduced, since the disposition of X5 electrodes 108 separately from stripe electrode 104 facilitates suppressing the current. The same explanations as made with respect to the display device according to Embodiment 1 with reference to FIG. 3 may be made also on the display device according to Embodiment 2.

### Embodiment 3

Now an example of the voltage vs. current characteristics of an organic thin film rectifying element in the case, in which the gate potential of a driving element formed of an organic thin film transistor is controlled to drive a light emitting element using the organic thin film rectifying element for a switching element, is described in FIG. 10. In FIG. 10, the rectifying element exhibits low resistance at a high voltage and high resistance at a low voltage. Since the electrical resistance is high below the threshold voltage in FIG. 10, any current does not flow substantially at a voltage lower than the threshold voltage. It is possible to charge and discharge the capacitor via the rectifying elements by applying a voltage higher than the threshold voltage to the rectifying elements. When a voltage lower than the threshold voltage (including a reverse bias voltage) is applied, the electric charges charged in the capacitor do not leak via the rectifying elements. Thus, it is possible to conduct matrix driving.

For realizing display at multiple gradation levels by making the light emitting element emit light at various levels of luminance, the gate voltage of the driving TFT, that is the accumulated voltage of capacitor 106, is controlled. The detailed control methods may be roughly classified into a first method and a second method. The first method changes the voltage difference between the data signal line (Y2 column electrode) and the gate portion (writing voltage) to control the accumulated voltage. The second method changes the ratio of the writing period to the duty period to control the accumulated voltage. If the first method is employed in the case in which a TFD is used for the switching element, the accumulated voltage will be the voltage difference obtained by subtracting the threshold voltage in FIG. 10 from the writing voltage, since any current does not flow substantially at a voltage lower than the threshold voltage. Therefore, the threshold voltage variation of the TFD element will directly cause gradation variation sometimes. If the second method is employed in the case in which a TFD is used for the switching element, a characteristics' variation or a slight driving voltage variation will cause a large variation in the current value, since the I-V characteristic curve is very steep in the high voltage range. In other words, since it is difficult to hold the current at a certain value, it will be impossible sometimes to control the accumulated electric charges, that is, to control the accumulated voltage, even if the writing period is controlled.

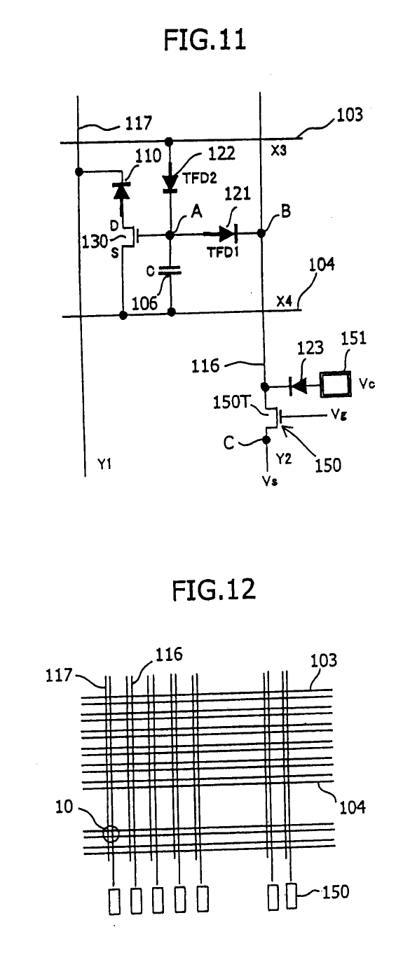

FIGS. 11 and 12 show the structure of a display device according to Embodiment 3 of the invention including the improvements for obviating the problems described above. The display device according to Embodiment 3 conducts dot matrix display by the duty driving system that addresses pixels 10 by the column electrodes formed of a set of stripe-shaped data electrodes (Y2 column electrodes) 116 and the line electrodes formed of a set of stripe-shaped scanning electrodes (X3 line electrodes) 103 formed in parallel to each other and crossing data electrodes 116. Each pixel is provided with light emitting section 110, transistor element 130, and at least one rectifying element 121. The gate electrode of transistor element 130 is connected electrically to data electrode 116 via rectifying element 121. A constant current circuit 150 is connected electrically to data electrode 116. Constant current circuit 150 is disposed for each data electrode 116 as shown in FIG. 12. Rectifying element 123 and constant voltage source 151 are connected to data electrode 116. The cathode terminal of rectifying element 121 and the cathode terminal of rectifying element 123 are connected to the Y2 column electrode 116.

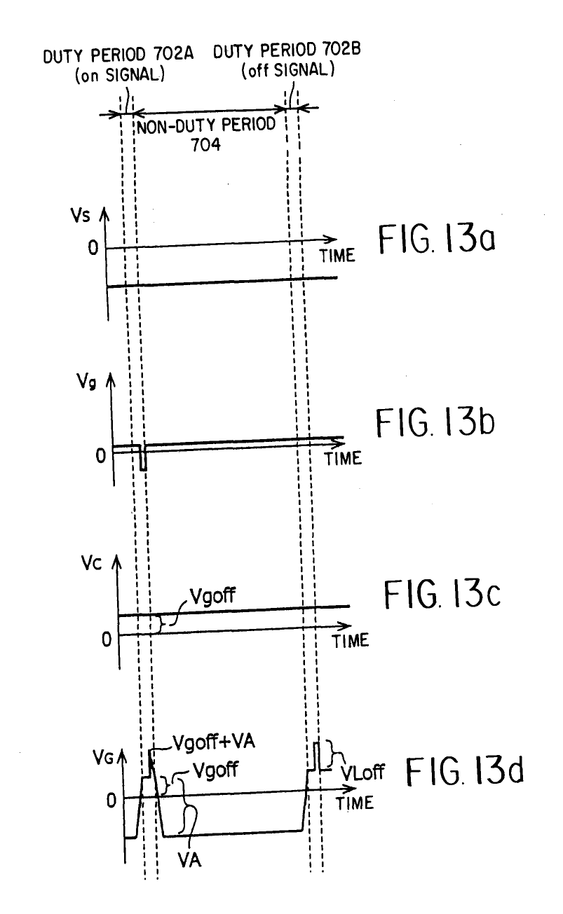

The steps of driving the display device according to Embodiment 3 will be described with reference to FIGS. 7 and 13. Although the description with reference to FIG. 7 is the same with the description made in connection with Embodiment 1, the waveform in the B portion is affected by constant current circuit 150, rectifying element 123, and constant voltage source 151. FIG. 13 is a timing chart describing the potentials of the electrodes in addition to FIG. 7. The FIG. 13(a) is the voltage waveform VS applied to Y2 column electrode 116 (C portion), FIG. 13(b) the control voltage waveform Vg of constant current circuit 150, and FIG. 13(c) the voltage VC applied from the constant voltage source. FIG. 13(d) is the gate voltage waveform VG of the A portion. The voltage waveform of the B portion obtained as the results of the waveforms described above is shown FIG. 7(e).

Although the gate voltage VG is Vgoff in the initialized state in the duty periods 701A and 702B according to Embodiment 3 in the same manner as according to Embodiment 1, the gate voltage VG increases instantaneously to (Vgoff+VA)=(2Vgoff−Vgon) in the second half of the duty period 701A due to the potential increase of X4 line electrode 104 (FIG. 13(d)). TFD 121 becomes electrically conductive due to the instantaneous gate voltage increase and the electric charges in the A portion are released to Y2 column electrode 116. The discharge is controlled by constant current circuit 150. When the control voltage waveform Vg of constant current circuit 150 is controlled to make constant current circuit 150 OFF as illustrated as the duty period 702B, the B portion potential increases to (2Vgoff−Vgon) same with the A portion potential, since TFD 121 is in the electrically conductive state. If described more exactly, although the increments of the voltages in the A and B portions decrease a little by the electrical capacitance component of the B potential, the voltage decrements are not essential. When the control voltage waveform Vg of constant current circuit 150 is controlled as illustrated as the duty period 702A to make a certain current flow for a certain period by the constant current circuit via TFD 121, the A portion potential (gate voltage VG) decreases corresponding to the released electric charges. Although constant current circuit 150 is capable of decreasing the A portion potential to the C portion voltage VS, it is enough for the display device according to Embodiment 3 to set the A portion potential around Vgoff. The other reason for setting the A portion potential at Vgoff will be described later. It is preferable to set the A portion potential at (Vgoff+δ) by adding the voltage drop δ across TFD 121 to Vgoff. As the potential of the X4 electrode is returned from VA to the ground potential (FIG. 7(f) at the end of the duty period 702A, the gate voltage lowers by VA (FIG. 13(d)). Thus, the gate potential VG is controlled between Vgon and Vgoff. Although 100% writing is conducted in the duty period 702A and 0% writing is conducted in the duty period 702B as illustrated exemplary in FIG. 7(d), it is easy to obtain intermediate gradation levels by intermediate degrees of writing. In other words, it is possible to control the control voltage waveform Vg of constant current circuit 150 in the second half of the duty period 702A so that the time for which the current flows (or the pulse width or the number of pulses) may be changed. Or, it is possible to control the control voltage waveform Vg so that the constant current value may be changed. Generally, the former method facilitates obtaining excellent gradation display stably. The operations in the non-duty period 704 are the same with the operations in connection with Embodiment 1.

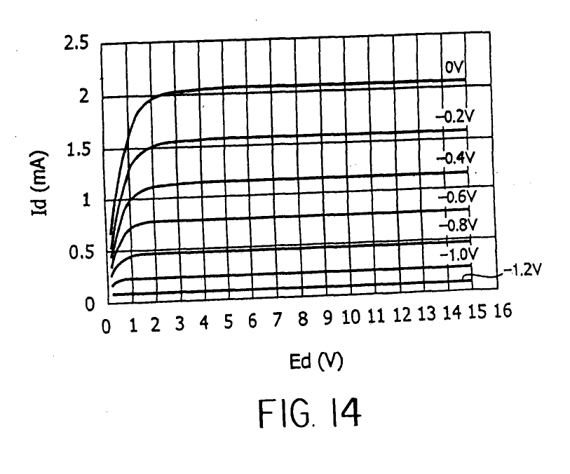

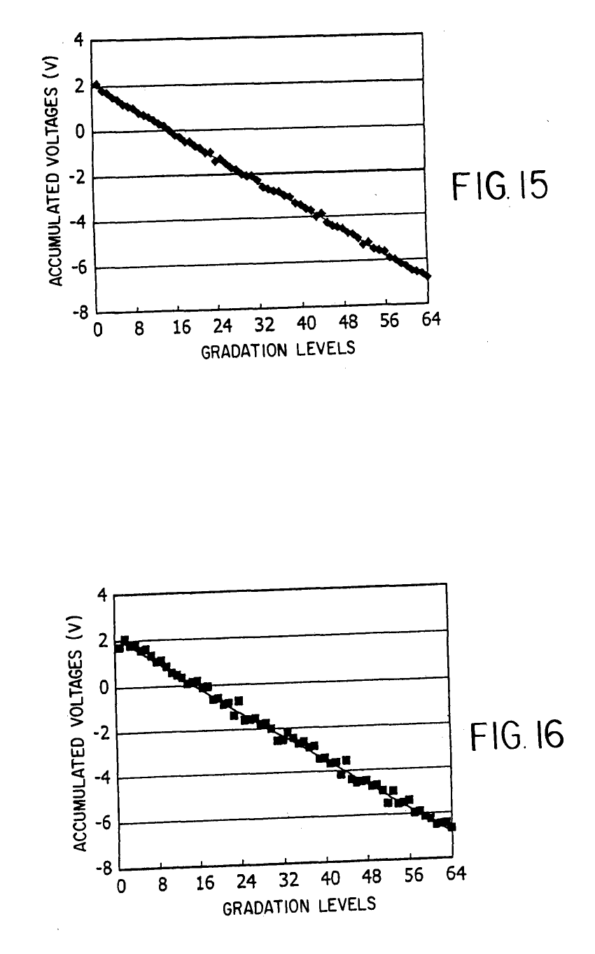

The characteristics of a field effect transistor 150T used in the constant current circuit are described in FIG. 14. FIG. 14 describes the drain current characteristics with respect to the drain voltage for the gate voltages between −1.2 V and 0 V. Field effect transistor 150T is in the saturation range above a certain drain voltage, in which the drain current is constant independently of the drain voltage. The current value in the saturation range is controlled easily by changing the gate voltage. In other words, the gate voltage of field effect transistor 150T is used for the control voltage Vg of constant current circuit 150. The ON/OFF of the current is conducted easily also by controlling the gate voltage. Therefore, by controlling the ON/OFF time ratio of the current with the gate voltage, the accumulated voltage value of capacitor 160 is controlled easily. In the structure shown in FIG. 11, it is preferable for the potential VS of the C portion in the constant current circuit to be different from the A portion potential by enough to make the field effect transistor conduct constant current operations in the saturation region. For example, if the potential difference necessary for the constant current circuit 150 to conduct constant current operations in the saturation region is put at Vk, the B portion potential Vb is made to be larger than Vs+Vk.

The B portion potential Vb should be set so that signal interference to the other lines may be prevented. Although the A portion potential of the line not in the duty period thereof is controlled between Vgoff and (Vgon +δ) corresponding to the state of writing and the B portion potential also changes corresponding to the controlled A portion potential, it is necessary for TFD 121 to be electrically nonconductive so that the B portion potential may be kept at a certain value. Therefore, it is preferable to bias TFD 121 in reverse. Due to this, the B portion potential is kept higher than the maximum potential value (Vgoff) of the A portion on the non-duty line.

As described above, the B portion potential Vb is controlled by the current control of constant current circuit 150 in the second half of the duty period 702A and 702B. However, when a resistance variation is caused in TFD 121, when a wiring resistance variation is caused, when electric charge leakage from the B portion is caused, or when excessive electric charge removal from the A portion is caused by the constant current circuit, there remains a certain possibility that the B portion potential will be lower than Vgoff. This is avoided by using rectifying element 123 and constant voltage source 151. By the use of rectifying element 123 and constant voltage source 151, the B portion potential is kept to be higher than Vgoff. In detail, constant voltage source 151 is set at Vgoff to feed necessary electric charges, when variations are caused in the writing operation or when electric charge leakage is caused, so that the B portion potential may be sustained to be higher than Vgoff.

As described above, the ON/OFF state of constant current circuit 150 is controlled easily by controlling the gate voltage (control voltage waveform Vg) of field effect transistor 150T. By the circuit configuration shown in FIG. 11, TFD's 121 and 122 for switching disposed in each pixel exhibit the functions of switches with low resistance that make the current fed from the constant current circuit flow through themselves in the duty period and the functions of holding the accumulated voltage in the non-duty period. The control of the accumulated charge amount in capacitor 160 in the duty period is conducted by controlling the value of the current fed from constant current circuit 150 outside the light emitting panel and the period of the current feed. The control of the current value fed from constant current circuit 150 and the period (pulse width or number of pulses) thereof is performed easily by the gate voltage control and the ON/OFF control of the gate voltage in the example of FIG. 11. Although Embodiment 3 is described in connection with the gate voltage control of field effect transistor 150T with stripe electrode Y2 116 and TFD 121, it is also possible to employ the gate opening time control of field effect transistor 150T. The gate opening time control of field effect transistor 150T is effective to prevent the threshold voltage variations of TFD's 121 and 122 or the driving voltage variations thereof from affecting adversely the light emitting current value.

### EXAMPLE 5

Constant current circuit 150 including field effect transistor 150T made of silicon and rectifying element 123 were connected to each of Y2 column electrodes 116 of the display device fabricated in the same manner as the display device according to Example 1 and constant voltage source 151 was connected to the other end of the rectifying element. Thus, the sample display device having the structure shown in FIG. 11 was fabricated.

### EXAMPLE 6

The sample display device according to Example 6 of the invention was fabricated in the same manner as the sample display device having the structure according to Example 5 except that neither rectifying element 123 nor constant voltage source 151 was connected to each of Y2 column electrodes 116 in the sample display device according to Example 6.

### EXAMPLE 7

The sample display device according to Example 7 of the invention was fabricated in the same manner as the sample display device having the structure according to Example 5 except that a constant voltage pulse supply was connected to each of Y2 column electrodes 116 in place of connecting constant current circuit 150 including field effect transistor 150T made of silicon, rectifying element 123, and constant voltage source 151.

### MEASUREMENT EXAMPLE

The samples according to Examples 5 through 7 fabricated as described above were driven at the frame frequency of 60 Hz (frame period of about 17 ms). Although the duty period was 17 ms/100=170 μs, the duty period was divided into two in the measurement example as described in FIGS. 7 and 14 and the data was initialized in the first half of the duty period. Therefore, the time allowed for writing data is the last 85 μs. Whether it is possible to write the data or not in this period of time is determined by the response time of the display device determined by the rectifying element resistance and the capacitor capacitance. Since the response times of the sample display devices according to Examples 5 through 7 were within the range between 8 and 10 μs, it was possible for the sample display devices according to Examples 5 through 7 to write the data practically.

When Vgon=2 V, Vgon=−9 V, Vt=20 V, and VA=11 V in the display devices according to Examples 5 through 7, the gate voltage (control voltage waveform VG) of transistor element 130 was controlled excellently between +2V and −7 V by the current value control of constant current circuit 150. The difference between Vgon=−9 V and the gate voltage of −7 V was set considering the foregoing voltage drop across TFD 121.

In the display devices according to Examples 5 and 6, the gate voltage of field effect transistor 150T in constant current circuit 150 was set at 0 V for turning on field effect transistor 150T and at −1.2 V for turning off field effect transistor 150T. Setting the C portion potential VS at −7 V and the voltage VC of constant voltage source 151 at 2 V, pulse width modulation of 64 gradation levels was conducted, with an increment of 1 μs, according to an increment of one gradation level for 70 μs within the data writing period of 85 μs, from which the start time of 10 μs of the field effect transistor element was subtracted. Field effect transistor 150T in constant current circuit 150 was in the saturation region, when the drain voltage thereof was 3 V or higher, the constant current operation was realized at the difference (9 V) between the C portion potential Vs and the voltage Vc of constant voltage source 151, and the drain current making the electric charges flow from the A portion in the ON-state was 10 μA.

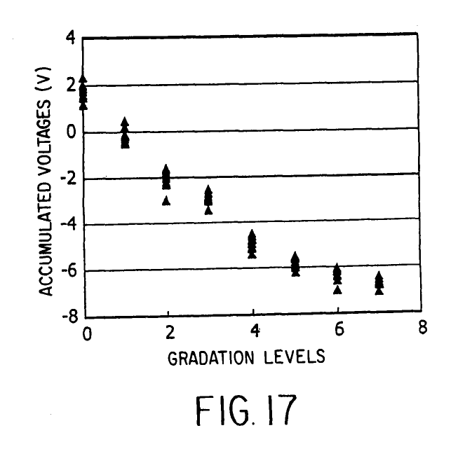

FIGS. 15 through 17 are graphs describing the accumulated voltage values of capacitor 106 at the gradation levels in the display devices according to Examples 5 through 7. As described in FIGS. 15 and 16, excellent correlation was obtained between the gradation levels and the accumulated voltages in the display devices according to Examples 5 and 6. The standard deviation with respect to the regression line was calculated for the display devices according to Examples 5 and 6. The standard deviation was 0.06 V for the display device according to Example 5 and 0.2 V for the display device according to Example 6. It is considered that the difference between the display devices according to Examples 5 and 6 was caused because the voltage of Y2 electrode 116 decreased temporarily to 2V or lower due to the resistance variation of rectifying element 121 and the leakage caused from Y2 electrode 116 and because the accumulated voltage of capacitor 106 in the non-duty period was affected by the voltage decrease described above.

The display device according to Example 7, in which the relation between the gradation levels and the accumulated voltages is described in FIG. 17, has a structure similar to the structure of the display device according to the Example 1. However, it is necessary for the display device according to Example 7 to control the A portion accumulated voltage by the ON/OFF of the voltage of Y2 column electrode 116 conducted by means of modulating the pulse width from the constant voltage pulse supply. Since writing was conducted by this driving method at a constant voltage, the voltage difference between the A portion and Y2 column electrode 116 decreased in association with the charge accumulation in capacitor 160 and linearity was not obtained between the accumulated voltage and the writing time (FIG. 17). Since the current value was changed by the resistance value variations of the rectifying element, large variations were caused in the accumulated voltage.

According to the invention, measures for manufacturing a display device such as an organic EL display panel on an inexpensive and flexible substrate using switching elements made of organic electronic materials have been provided. Especially in the case of using an organic thin film rectifying element for the switching element, gradation levels have been obtained with excellent stability.

In the above, although the invention has been described in connection with the embodiments thereof, they are exemplary and not limiting upon the scope of the invention, Therefore, many modifications and variations may be made to the techniques and structures described and illustrated herein without departing from the spirit and scope of the invention.

1. A display device comprising:
a substrate;
a first set of stripe electrodes formed in parallel to each other on the substrate;
a second set of stripe electrodes formed on the substrate corresponding to the respective stripe electrodes of the first set, the stripe electrodes of the second set being formed in parallel to each other and in parallel to the stripe electrodes of the first set;
a third set of stripe electrodes formed in parallel to each other on the substrate, the stripe electrodes of the third set crossing the stripe electrodes of the first and second sets;
a fourth set of stripe electrodes formed on the substrate corresponding to the respective stripe electrodes of the third set, the fourth set being formed in parallel to each other and in parallel to the stripe electrodes of the third set;
a fifth set of stripe electrodes formed on the substrate corresponding to the respective stripe electrodes of the third set, the stripe electrodes of the fifth set being formed in parallel to each other and in parallel to the stripe electrodes of the third and fourth sets;
pixels at the respective points on the substrate, where any of the stripe electrodes of the first set and any of the stripe electrodes of the fourth set cross each other on two levels;
each of the pixels comprising:
a light emitting section, one of the electrodes of which is connected electrically to the stripe electrode of the first set corresponding to the each of the pixels;
a transistor element connected electrically to the stripe electrode of the fourth set corresponding to each of the pixels and the other one of the electrodes of the light emitting section, in order to control the current flowing through the light emitting section from the stripe electrode of the first set to the stripe electrode of the fourth set or vice versa in each of the pixels;
a first rectifying element connected electrically to the gate electrode of the transistor element and the stripe electrode of the second set corresponding to each of the pixels;
a second rectifying element connected electrically to the gate electrode of the transistor element and the stripe electrode of the third set corresponding to each of the pixels;
a capacitor connected electrically to the gate electrode of the transistor element and the stripe electrode of the fifth set corresponding to each of the pixels; and
the first rectifying element and the second rectifying element being connected such that the forward direction of the first rectifying element and the forward direction of the second rectifying element coincide with each other between the stripe electrodes of the second and third sets in the each of the pixels.

2. The display device according to claim 1, wherein at least one of the transistor, the rectifying elements and the capacitor comprises an organic electronic material.

3. A display device comprising:
a substrate;
a set of stripe-shaped data electrodes formed in parallel to each other on the substrate;
a set of stripe-shaped scanning electrodes formed in parallel to each other on the substrate, the scanning electrodes crossing the data electrodes;
pixels at respective points on the substrate where any of the data electrodes and any of the scanning electrodes cross each other on two levels;
each of the pixels comprising: a light emitting section, a transistor element controlling the current flowing through the light emitting section, a rectifying element, and the gate electrode of the transistor element being connected electrically to the relevant data electrode via the rectifying element; and
constant current circuits connected electrically to the respective data electrodes.

4. The display device according to claim 3, the display device further comprising:
other rectifying elements and constant voltage sources;
each of the constant voltage sources being connected electrically to the relevant data electrode, in parallel to the relevant constant current circuit, via each of the other rectifying elements; and
wherein the polarity of the terminal of the other rectifying element connected to the relevant data electrode is the same as the polarity of the terminal of the rectifying element in each of the pixels connected to the relevant data electrode.

5. The display device according to claim 3, wherein the rectifying element connected to each of the pixels comprises an organic electronic material.

6. The display device according to claim 4, wherein the rectifying element connected to each of the pixels comprises an organic electronic material.
